(19) United States
(12) Patent Application Publication
(10) Pub. No.: US 2025/0201612 A1
(43) Pub. Date: Jun. 19, 2025

(54) TRANSFER UNIT, AND SUBSTRATE PROCESSING APPARATUS INCLUDING THE SAME

(71) Applicant: SEMES CO., LTD., Cheonan-si (KR)

(72) Inventors: Kyo Bong KIM, Seongnam-si (KR); Sang Oh KIM, Seoul (KR); Ki Won HAN, Anseong-si (KR); Hee Jae BYUN, Yongin-si (KR); Doo Hyun BAEK, Hwaseong-si (KR); Hee Chan KIM, Hwaseong-si (KR)

(73) Assignee: SEMES CO., LTD., Cheonan-si (KR)

(21) Appl. No.: 18/978,173

(22) Filed: Dec. 12, 2024

(30) Foreign Application Priority Data
Dec. 13, 2023 (KR) 10-2023-0181004

(51) Int. Cl. H01L 21/677; B25J 5/02; H01F 7/20; H01L 21/687

(52) U.S. Cl. CPC H01L 21/67709; B25J 5/02; H01F 7/206; H01F 27/306; H01L 21/68707; B25J 11/0095

(57) ABSTRACT

Disclosed is a substrate transfer device including: a robot unit; and a moving unit configured to move the robot unit in a magnetic levitation manner along a first direction (X axis), in which the moving unit includes: a moving body including an electromagnet module that provides power for magnetic levitation; and a rail structure with a guide rail installed along the first direction to define a movement path of the moving body, and the electromagnet module includes: a body; electromagnets provided on an upper surface, a lower surface, and one side surface of the body the electromagnets being configured to levitate and guide the moving body; and an epoxy molding part formed by molding the body and the electromagnets with an epoxy resin.

### CROSS-REFERENCE TO RELATED APPLICATIONS

This application claims priority to and the benefit of Korean Patent Application No. 10-2023-0181004 filed in the Korean Intellectual Property Office on Dec. 13, 2023, the entire contents of which are incorporated herein by reference.

### TECHNICAL FIELD

The present invention relates to a transfer unit and a substrate processing apparatus including the same.

### BACKGROUND ART

A semiconductor manufacturing process is a process of manufacturing semiconductor products capable of processing electrical signals, and includes a front-end process (pre-process) of forming a pattern on a wafer through a process, such as oxidation, exposure, etching, ion implantation, and deposition, and a back-end process (post-process) of manufacturing a semiconductor package in the form of a finished product through processes, such as dicing, die bonding, wiring, molding, marking, and testing on a patterned wafer. The semiconductor manufacturing process is carried out in the semiconductor manufacturing facility for performing each process, and each semiconductor manufacturing facility is configured to discharge after performing process processing on the input wafer. One or more wafer transfer robots for transferring wafers exist in semiconductor manufacturing facilities.

Meanwhile, as the level of requirement for cleanliness of semiconductor manufacturing facilities increases due to the miniaturization of semiconductor manufacturing processes, measures to minimize friction in semiconductor manufacturing facilities are being discussed. In particular, in the case of a wafer transfer robot, a magnetic levitation type driving device capable of non-contact driving is considered because particles may be generated by friction in the case of an existing contact-type driving device using a wheel.

FIG. 1 is a diagram illustrating a magnetic levitation type substrate transfer device according to the related art.

Referring to FIG. 1, levitation electromagnets, guide electromagnets, gap sensors, and the like are attached to a substrate transfer body, so assembly tolerance increases when electromagnets or gap sensors are replaced, and assembly errors occur according to operators, making it difficult to make high-precision control due to differences between a mathematical model of the transfer body and an actual posture. In particular, problems, such as loosening the bolt for fixing the gap sensor due to high-frequency vibration occur during long-term driving.

In addition, as the distance between the electromagnet and the amplifier increases, switch noise and heat generation problems may occur.

### PRIOR ART LITERATURE

### Patent Document

Korean Patent Laid-Open Application No. 10-2022-0040927

### SUMMARY OF THE INVENTION

The present invention has been made in an effort to provide a transfer unit that is easily assembled and maintained, and is capable of easily discharging heat generated from an electromagnet, and a substrate processing apparatus including the same.

The present invention has also been made in an effort to provide a transfer unit capable of precisely predicting a posture of a transfer body and controlling a high-precision magnetic levitation, and a substrate processing apparatus including the same.

The present invention has also been made in an effort to provide a transfer unit capable of preventing damage to an electromagnet module, and a substrate processing apparatus including the same.

The object of the present invention is not limited thereto, and other objects not mentioned will be clearly understood by those of ordinary skill in the art from the following description.

An exemplary embodiment of the present invention provides a substrate transfer device comprising: a robot unit; and a moving unit configured to move the robot unit in a magnetic levitation manner along a first direction (X axis), wherein the moving unit includes: a moving body including an electromagnet module that provides power for magnetic levitation; and a rail structure with a guide rail installed along the first direction to define a movement path of the moving body, and the electromagnet module includes: a body; electromagnets provided on an upper surface, a lower surface, and one side surface of the body, the electromagnets being configured to levitate and guide the moving body; and an epoxy molding part formed by molding the body and the electromagnets with an epoxy resin.

According to the exemplary embodiment of the present invention, the electromagnet module further may include gap sensors fixed to the body and configured to measure a levitation directional gap and a guide directional gap of the moving body, and the gap sensors are embedded in the epoxy molding part.

According to the exemplary embodiment of the present invention, the electromagnets may include an upper electromagnet provided on the upper surface of the body to levitate the moving body in a levitation direction (Z-axis), a lower electromagnet provided on a lower surface of the body, and a guide electromagnet provided on one side surface of the body to guide the moving body in a horizontal direction (Y-axis).

According to the exemplary embodiment of the present invention, the body may include: a first core formed to protrude upwardly from the upper surface of the body and inserted into a coil of the upper electromagnet; a second core formed to protrude downwardly from the lower surface of the body and inserted into a coil of the lower electromagnet; and a third core formed to protrude laterally from one side of the body and inserted into a coil of the guide electromagnet.

According to the exemplary embodiment of the present invention, the first core, the second core, and the third core may be provided such that the ends of the cores protrude from a surface of the epoxy molding part.

According to the exemplary embodiment of the present invention, each of the electromagnets may include a core and a coil provided to surround the core, and the core may be integrally formed with the body.

According to the exemplary embodiment of the present invention, the rail structure further includes a base plate extending along the first direction, and the guide rail is provided on an upper portion of the base plate and surrounds the electromagnet module and may be open toward the outside of the movement path.

According to the exemplary embodiment of the present invention, the guide rail has a ‘C’-shape that may be open to the outside.

According to the exemplary embodiment of the present invention, the moving body may further include a moving plate supporting the robot unit, the electromagnet modules are disposed on front opposite sides and rear opposite sides of the moving plate, respectively, an amplifier consisting of a power amplifier that supplies current may be connected to the electromagnet module, and the amplifier may be disposed on opposite sides of the moving plate to be positioned between the electromagnet modules.

According to the exemplary embodiment of the present invention, a linear motor configured to provide propulsive force to the moving body.

According to the exemplary embodiment of the present invention, the moving body may further include: a side guide roller provided on the moving plate and configured to rotate while contacting a side surface of the guide rail; and an upper guide roller provided on the moving plate and configured to rotate while contacting an upper surface of the guide rail.

Another exemplary embodiment of the present invention provides a substrate processing apparatus comprising: process chambers which are arranged along a first direction (X axis) and in which a process is performed on a substrate; a robot unit including a hand supporting the substrate to transfer the substrate to the process chamber; and a moving unit configured to move the robot unit in a magnetic levitation manner along the first direction, wherein the moving unit includes: a moving body including an electromagnet module that provides power for magnetic levitation; and a rail structure with a guide rail installed along the first direction to define a movement path of the moving body, and the electromagnet module includes: a body; electromagnets provided on an upper surface, a lower surface, and one side surface of the body and for levitating and guiding the moving body; gap sensors fixed to the body and for measuring a levitation directional gap and a guide directional gap of the moving body; and an epoxy molding part formed by molding the body, the electromagnets, and the gap sensors with an epoxy resin.

According to the exemplary embodiment of the present invention, the electromagnets may include an upper electromagnet disposed on the upper surface of the body to levitate the moving body in a levitation direction (Z-axis), a lower electromagnet provided on the lower surface of the body, and a guide electromagnet provided on one side surface of the body to guide the moving body in a horizontal direction (Y-axis).

According to the exemplary embodiment of the present invention, the body may include: a first core formed to protrude upwardly from the upper surface of the body and surrounded by a coil of the upper electromagnet; a second core formed to protrude downwardly from the lower surface of the body and surrounded by a coil of the lower electromagnet; and a third core formed to protrude laterally from one side of the body and surrounded by a coil of the guide electromagnet.

According to the exemplary embodiment of the present invention, the first core, the second core, and the third core may be provided such that the ends of the cores protrude from a surface of the epoxy molding part.

According to the exemplary embodiment of the present invention, the rail structure may further include a base plate extending along the first direction, and the guide rail is provided on an upper portion of the base plate and has a “C”-shape that surrounds the electromagnet module and may be open toward the outside of the movement path.

According to the exemplary embodiment of the present invention, the moving body may further include a moving plate supporting the robot unit, the electromagnet modules are disposed on front opposite sides and rear opposite sides of the moving plate, respectively, an amplifier consisting of a power amplifier that supplies current is connected to the electromagnet modules, and the amplifier may be disposed on opposite sides of the moving plate to be positioned between the electromagnet modules.

Still another exemplary embodiment of the present invention provides a substrate transfer device comprising: a robot unit including a hand supporting the substrate to transfer the substrate to a process chamber; and a moving unit for moving the robot unit in a magnetic levitation manner along the first direction, wherein the moving unit includes: a moving body including a moving plate supporting the robot unit and electromagnet modules providing levitation force for magnetic levitation of the moving plate; a rail structure with a guide rail installed along the first direction on a base plate to provide a movement path of the moving body; and a linear motor provided between the moving body and the rail structure and providing propulsive force to the moving body, the electromagnet module includes: a body mounted on the moving plate by a fixing bracket; electromagnets provided on an upper surface, a lower surface, and one side surface of the body and for levitating and guiding the moving body; gap sensors fixed to the body and for measuring a levitation directional gap and a guide directional gap of the moving body; and an epoxy molding part formed by molding the body, the electromagnets, and the gap sensors with an epoxy resin, and the guide rail has a ‘C’-shape that surrounds the electromagnet module and may be open toward the outside of the movement path.

According to the exemplary embodiment of the present invention, the electromagnets may include an upper electromagnet provided on the upper surface of the body to levitate the moving body in a levitation direction (Z-axis), a lower electromagnet provided on the lower surface of the body, and a guide electromagnet provided on one side surface of the body to guide the moving body in a horizontal direction (Y-axis), and the body may include: a first core formed to protrude upwardly from the upper surface of the body and surrounded by a coil of the upper electromagnet; a second core formed to protrude downwardly from the lower surface of the body and surrounded by a coil of the lower electromagnet; and a third core formed to protrude laterally from one side of the body and surrounded by a coil of the guide electromagnet.

According to the exemplary embodiment of the present invention, the first core, the second core, and the third core are provided such that ends of the cores protrude from a surface of the epoxy molding part, the electromagnet modules are disposed on front opposite sides and rear opposite sides of the moving plate, respectively, an amplifier consisting of a power amplifier that supplies current is connected to the electromagnet module, and the amplifier may be disposed on opposite sides of the moving plate to be positioned between the electromagnet modules.

According to the exemplary embodiment of the present invention, there are special effects of easily assembling and maintaining the transfer unit, and easily dissipating heat generated by the electromagnet.

According to the exemplary embodiment of the present invention, there are special effects of enabling precise posture prediction of the transfer body and high-precision magnetic levitation control.

According to the exemplary embodiment of the present invention, damage to the electromagnet module may be prevented.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a diagram illustrating a magnetic levitation type substrate transfer device according to the related art.

FIG. 2 is a diagram illustrating a magnetic levitation type substrate transfer device according to an exemplary embodiment of the present invention.

FIG. 3 is a perspective view illustrating a moving unit illustrated in FIG. 2.

FIG. 4 is a front view of the moving unit illustrated in FIG. 3.

FIGS. 5 and 6 are perspective views illustrating an electromagnet module.

FIG. 7 is an exploded perspective view of the electromagnet module.

FIG. 8 is a front view of the electromagnet module.

FIG. 9 is a diagram illustrating a semiconductor manufacturing facility to which the magnetic levitation type substrate transfer device according to the present invention is applied.

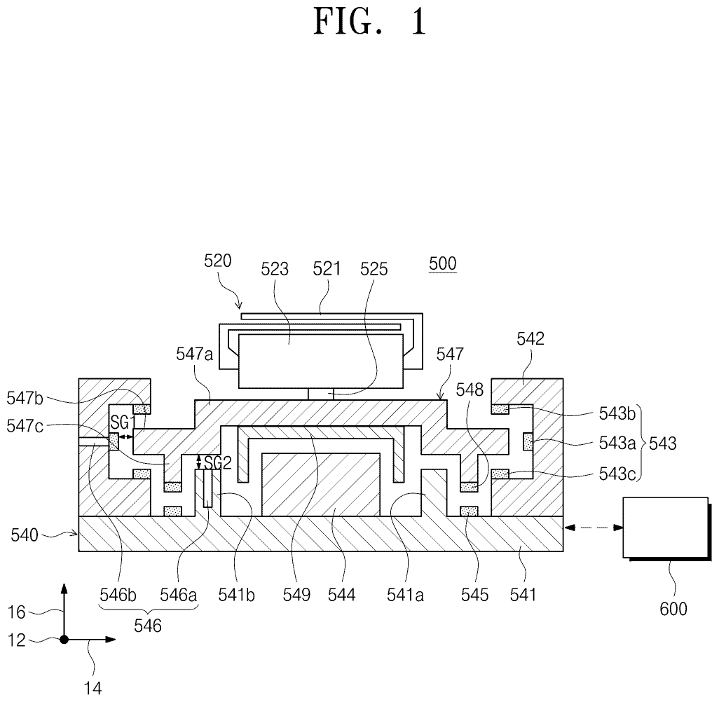

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, constituent elements, and components described in the specification or a combination thereof, and do not exclude a possibility of the existence or addition of one or more other characteristics, numbers, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

The present invention aims to provide a transfer unit capable of easily discharging heat generated by an electromagnet module and an amplifier while being easy to assemble and maintain, and a substrate processing apparatus including the same.

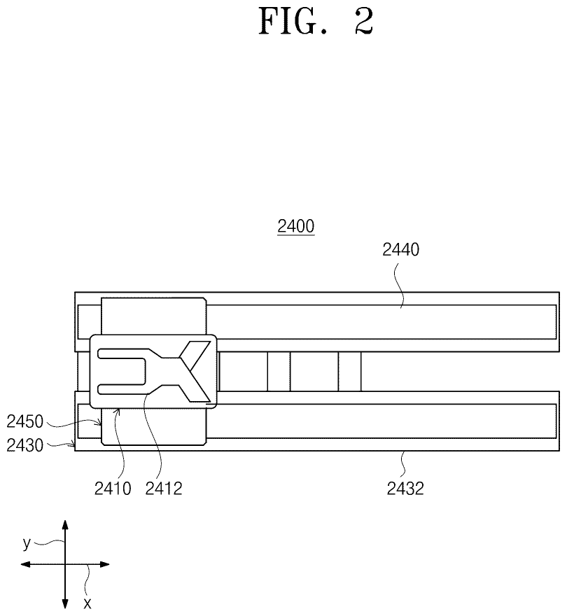

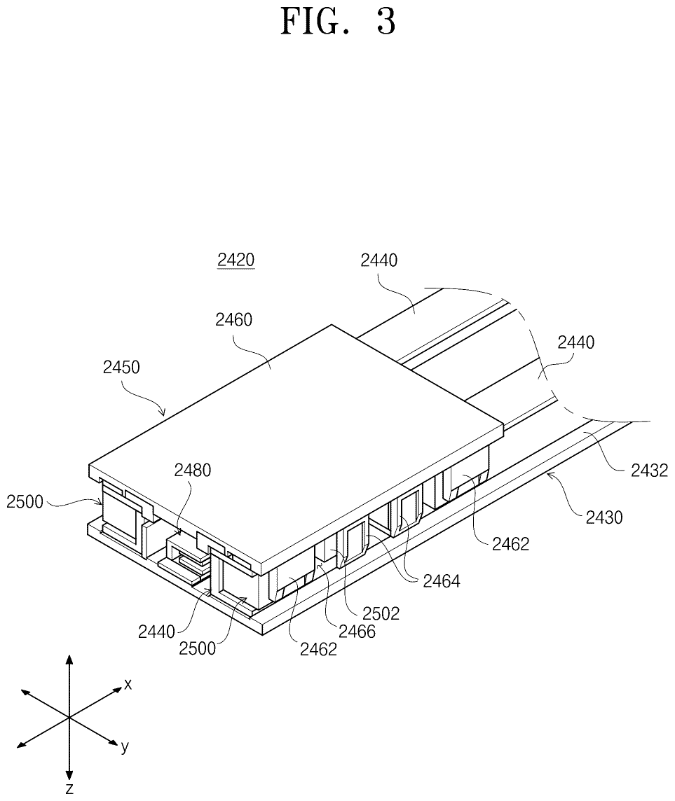

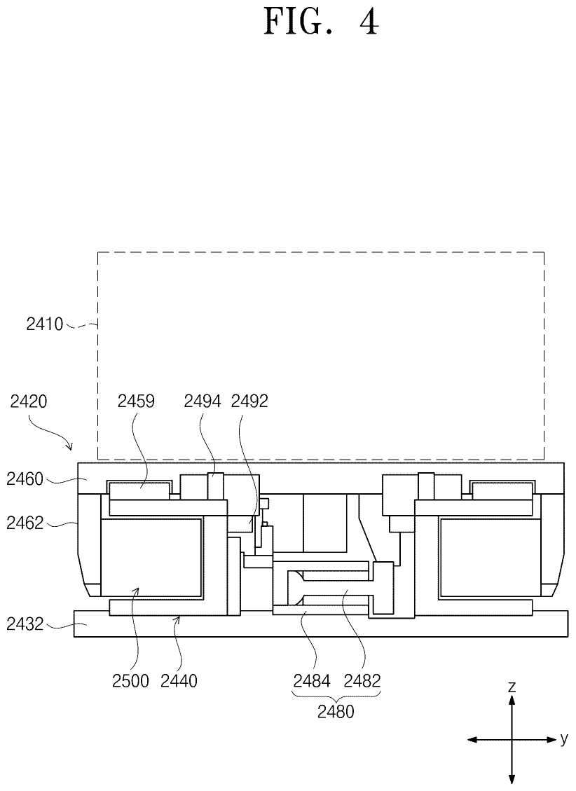

FIG. 2 is a diagram illustrating a magnetic levitation type substrate transfer device according to an exemplary embodiment of the present invention, FIG. 3 is a perspective view illustrating a moving unit illustrated in FIG. 2, and FIG. 4 is a front view of the moving unit illustrated in FIG. 3.

Referring to FIGS. 2 to 4, a substrate transfer device 2400 may include a robot unit 2410 and a moving unit 2420.

The robot unit 2410 includes a hand 2412 that supports the substrate to transfer the substrate, and the robot unit 2410 is a known technology used in the semiconductor field, and a detailed description thereof is omitted.

The moving unit 2420 is a device for moving the robot unit 2410 in a magnetic levitation manner along a first direction. The moving unit 2420 may include a rail structure 2430, a linear motor 2480, and a moving body 2450.

The moving body 2450 may include a moving plate 2460, electromagnet modules 2500, amplifiers 2502, and guide rollers 2492 and 2494.

The moving plate 2460 has a rectangular plate shape to allow the robot unit to be seated thereon. The robot unit 2410 is installed on the moving plate 2460. The moving plate 2460 is positioned to be spaced apart from an upper portion of the rail structure 2430 by a predetermined distance.

The electromagnet modules 2500 provide levitation force for magnetic levitation of the moving plate 2460. In the present exemplary embodiment, the moving body 2450 has four electromagnet modules 2500. When viewed in a plan view, the electromagnet modules 2500 may be disposed at two front and two rear opposite sides of the moving plate 2460. The electromagnet module 2500 may provide stable levitation force to the moving plate 2460 by being disposed at four corners of the moving plate 2460. The electromagnet module 2500 may be fixed to a first fixing bracket 2462 extending downwardly from opposite sides of the moving plate 2460.

According to the arrangement of the electromagnet module 2500, two first fixing brackets 2462 may be configured in the left-right direction (y direction) of the moving plate 2460 and two in the front-rear direction (x direction), for a total of four.

The moving body 2450 may form an open space 2466 by arranging the first fixing brackets 2462 to be spaced apart from each other under the moving plate 2460 in the front-rear direction (x direction). Heat of the electromagnet module 2500 may escape through the open space 2466 and further, the electromagnet module 2500 may be easily assembled and maintained because an operator is capable of accessing the inside through the open space 2466.

An amplifier 2502 consisting of a power amplifier that supplies a current to the electromagnet module 2500 is connected to each of the electromagnet modules 2500. The amplifier 2502 is provided as a set with the electromagnet module 2500, and the amplifier 2502 may be disposed on both sides of the moving plate 2460 to be positioned between the electromagnet modules 2500. The amplifier 2502 may be fixed to second fixing brackets 2464 extending downwardly from opposite sides of the moving plate 2460. The amplifier 2502 is disposed side by side at a close distance to the electromagnet module 2500, thereby minimizing switching noise and heat generation. Also, since the amplifier 2502 is located on the side of the moving plate 2460, heat dissipation to the air is easy.

Meanwhile, the moving body 2450 may include a side guide roller 2492 provided under the moving plate 2460 and configured to rotate in contact with the side surface of the guide rail 2440, and an upper guide roller 2494 provided under the moving plate 2460 and configured to rotate in contact with an upper surface of the guide rail 2440. Referring to FIGS. 3 and 4, the side guide roller 2492 may rotate in contact with the side surface of the guide rail 2440 under the moving plate 2460, and may prevent the moving body 2450 from being separated from the guide rail 2440. The upper guide roller 2494 may rotate in contact with the upper surface of the guide rail 2440 under the moving plate 2460, and may prevent the moving plate 2460 from descending and colliding with the guide rail 2440 even when power to the electromagnet module 2500 is cut off. Meanwhile, stoppers 2459 for stopping the moving body 2450 may be provided on lower opposite sides of the moving plate 2460.

The rail structure 2430 provides a movement path of the moving body 2450. The rail structure 2430 may include a base plate 2432 extending along a movement path, and a guide rail 2440 provided on the base plate 2432 and formed to surround the electromagnet module 2500 of the moving body 2450. Since the guide rail 2440 is configured to have a ‘c’ shape that surrounds the electromagnet module 2500 but is open toward the outside of the movement path, it is possible to constantly access the electromagnet module 2500 from the outside, so that the assembly and maintenance of the electromagnet module 2500 are easy and heat generated by the electromagnet module 2500 may be easily discharged to the outside.

Referring to FIGS. 3 and 4, the rail structure 2430 extends in the front-rear direction (x-direction), and the moving body 2450 may be configured to move in the front-rear direction (x-direction) along the rail structure 2430. The base plate 2432 is disposed on the bottom surface to extend in the front-rear direction (x-direction).

The guide rails 2440 may be provided in a pair formed at both ends of the upper surface of the base plate 2432. The guide rails 2440 are configured in a pair on opposite sides of the base plate 2432 in the left-right direction (y-direction), and each of the guide rails 2440 may be configured identically, but open portions thereof may be configured in opposite directions. The guide rails 2440 may be made of a metal material that generates traction force with respect to the electromagnet module 2500. The electromagnet modules 2500 of the moving body 2450 may levitate the moving body 2450 by generating traction force with respect to the guide rail 2440.

The linear motor 2480 provides propulsive force to the moving plate 2460. The linear motor 2480 may be a Linear Synchronous Motor (LSM) using a coil (electromagnet). As an example, the linear motor 2480 may include a mover 2482 and a stator 2484. The stator 2484 may be positioned between the guide rails 2440 at a central portion of the base plate 2432. The mover 2482 is fixed to the moving plate 2460. The linear motor 2480 generates the propulsive force through interaction of magnetic fields generated by the stator 2484 installed at the base plate 2432 and the mover 2482 installed at the moving plate 2460.

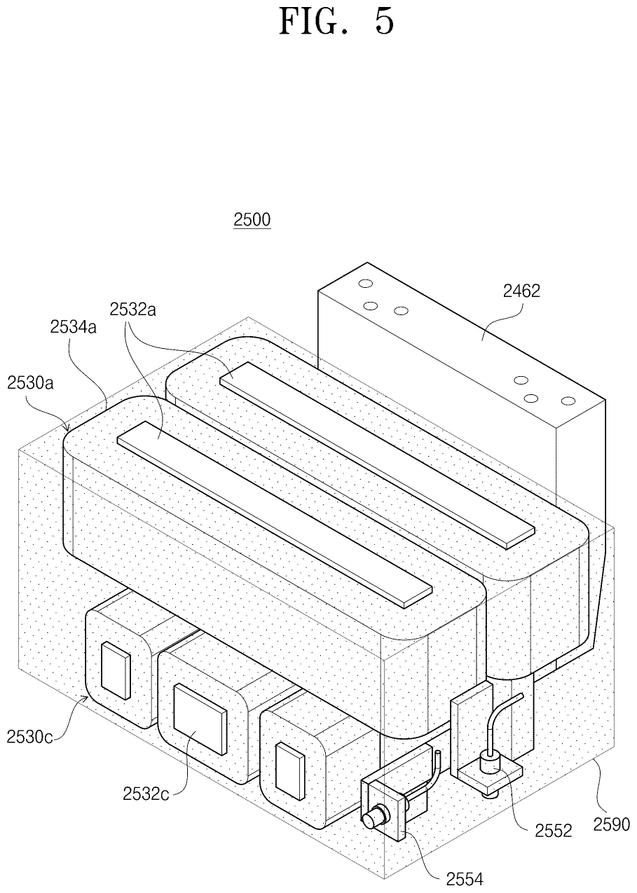

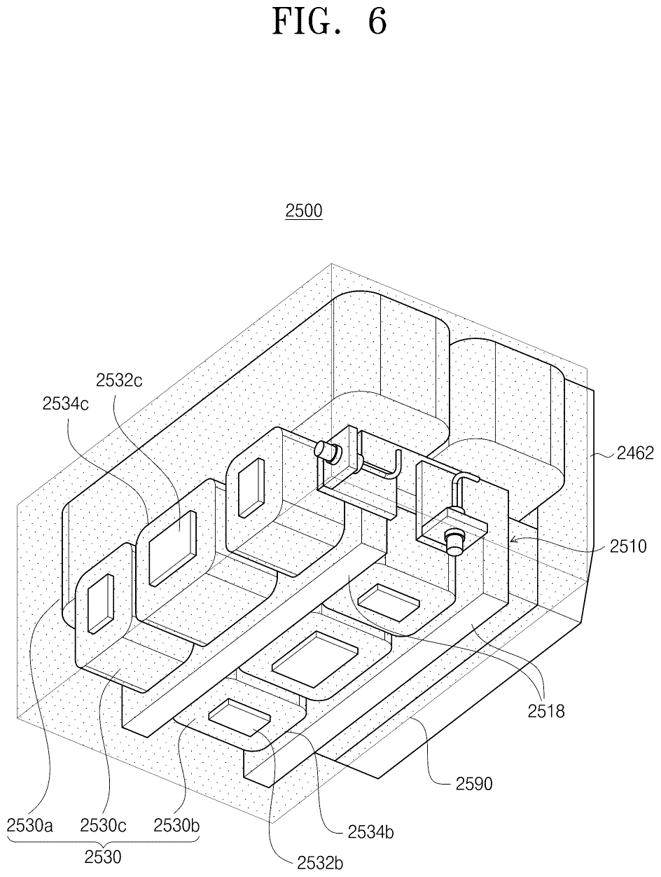

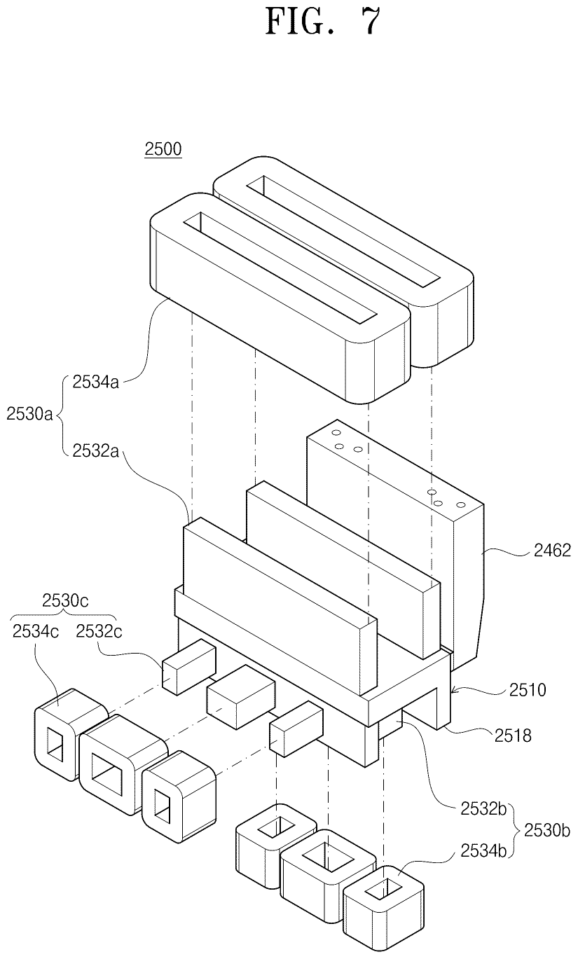

FIGS. 5 and 6 are perspective views illustrating the electromagnet module, and FIG. 7 is an exploded perspective view of the electromagnet module.

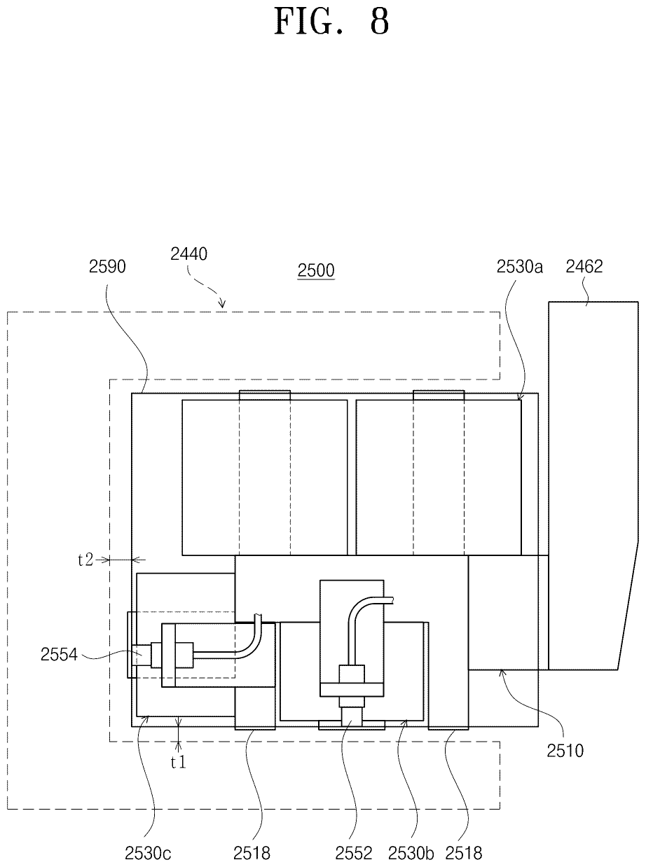

Referring to FIGS. 5 to 8, the electromagnet module 2500 may include a body 2510, electromagnets 2530, gap sensors 2552 and 2554, and an epoxy molding part 2590.

The electromagnets 2530 may be provided on a top surface, a bottom surface, and one side surface of the body 2510 to levitate and guide the moving body 2450. For example, the electromagnets 2530 may include an upper electromagnet 2530a provided on the top surface of the body 2510 to levitate the moving body 2450 in a levitation direction (Z-axis direction), a lower electromagnet 2530b provided on the bottom surface of the body 2510, and a guide electromagnet 2530c provided on one side surface of the body 2510 to guide the moving body 2450 in the horizontal direction (Y-axis direction).

The electromagnet 2530 may include a core and a coil provided to surround the core. The core may be provided integrally with the body 2510. For example, the body 2510 may include a first core 2532a, a second core 2532b, and a third core 2532c. The first core 2532a is formed to protrude upwardly from the top surface of the body 2510, and is provided to be inserted into the coil 2534a of the upper electromagnet 2530a. The second core 2532b is formed to protrude downwardly from the lower surface of the body 2510, and is provided to be inserted into that the coil 2534b of the lower electromagnet 2530b. The third core 2532c is formed to protrude laterally from one side of the body 2510, and is provided to be inserted into the coil 2534c of the guide electromagnet 2530c. The first core 2532a, the second core 2532b, and the third core 2532c are provided such that ends thereof protrude from the outer surface of the epoxy molding part 2590. Additionally, the body 2510 includes two legs 2518 protruding downwardly and protruding from a bottom surface of the epoxy molding part 2590. As described above, the electromagnet module 2500 is provided such that the core of the electromagnet 2530 and a portion of the body 2510 protrude more than the epoxy molding part 2590, thereby preventing the epoxy molding part 2590 from colliding with the guide rail 2440 due to vibrations that occur during the operation of the moving body 2450. Therefore, damage to the epoxy molding part 2590 may be prevented during magnetic levitation of the moving body 2450.

The gap sensors 2552 and 2554 are fixed to the body 2510. The gap sensors 2552 and 2554 measure a levitation direction gap and a guiding direction gap of the moving body 2450. As an example, the gap sensors 2552 and 2554 may include a first gap sensor 2552 to measure a levitation directional gap t1 of the moving body 2450, and a second gap sensor 2554 to measure a guiding directional gap t2 of the moving body 2450. A controller (not illustrated) that controls the electromagnet modules 2500 may control the current provided to the electromagnet module 2500 so that the gap between the electromagnet module 2500 and the guide rail 2440 is maintained by a predetermined distance, and may adjust the magnetic force of the electromagnet module 2500 by controlling the current.

The epoxy molding part 2590 is provided to surround the body 2510, the electromagnets 2530, and the gap sensors 2552 and 2554. That is, the body 2510, the electromagnets 2530, and the gap sensors 2552 and 2554 may be provided as an integrated module molded with an epoxy resin. Accordingly, convenience of assembling and maintaining the electromagnet module 2500 may be secured, and since the electromagnet 2530 and the gap sensors 2542 and 2544 are not twisted or released, it is possible to precisely predict the posture of the transfer body and control a high-precision magnetic levitation.

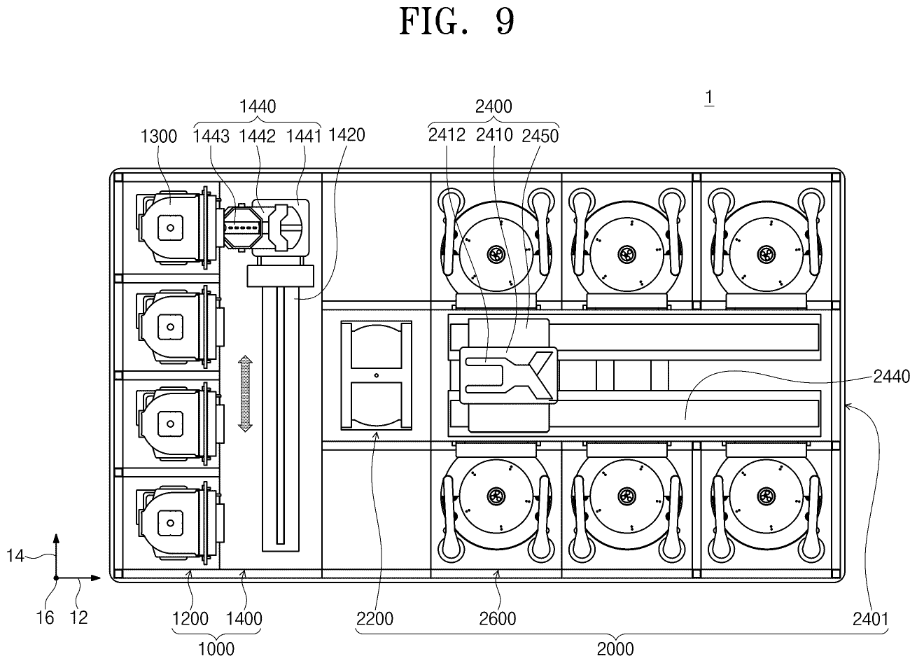

FIG. 9 is a diagram illustrating a semiconductor manufacturing facility to which the magnetic levitation type substrate transfer device according to the present invention is applied

The semiconductor manufacturing facility 1, to which the magnetic levitation type substrate transfer device 2400 according to the present invention is applicable, describes an apparatus for performing a substrate cleaning process as an example. However, the present invention is not limited thereto, and is applicable to various apparatuses for performing semiconductor processing processes, such as etching, coating, development, and deposition, and the present invention is not limited to an apparatus for a specific process and may be applied to any kind of facility.

Referring to FIG. 9, a semiconductor manufacturing facility 1 according to the exemplary embodiment of the present invention includes an index module 1000 and a process module 2000. The index module 1000 includes a load port 1200 and a transfer frame 1400. The load port 1200, the transfer frame 1400, and the process module 2000 are sequentially arranged in series. Hereinafter, a direction in which the load port 1200, the transfer frame 1400, and the process module 2000 are arranged is referred to as a first direction 12. When viewed above, a direction vertical to the first direction 12 is referred to as a second direction 14, and a direction vertical to a plane including the first direction 12 and the second direction 14 is referred to as a third direction 16.

A carrier 1300 in which a substrate W is accommodated is seated on the load port 1200. The load port 1200 is provided in plurality, and the plurality of load ports 1200 is arranged in series in the second direction 14. In FIG. 9, it is illustrated that four load ports 1200 are provided. However, the number of load ports 1200 may also be increased or decreased according to process efficiency of the process module 2000 and a condition, such as footprint. A slot (not illustrated) provided to support an edge of the substrate W is formed in the carrier 1300. The slot is provided in plurality in the third direction 16. The substrates W are positioned in the carrier 1300 to be stacked while being spaced apart from each other in the third direction 16. As the carrier 1300, a Front Opening Unified Pod (FOUP) may be used.

The process module 2000 includes a buffer unit 2200, a transfer chamber 2401, and a process chamber 2600. A longitudinal direction of the transfer chamber 2401 is disposed parallel to the first direction (x-axis direction). Process chambers 2600 are disposed at one side and the other side of the transfer chamber 2401 in the second direction 14. The process chambers 2600 located on one side of the transfer chamber 2401 and the process chambers 2600 located on the other side of the transfer chamber 2401 may be provided to be symmetrical to each other with respect to the transfer chamber 2401. Some of the process chambers 2600 are disposed in the longitudinal direction of the transfer chamber 2401. Further, some of the process chambers 2600 are disposed to be stacked with each other. That is, the process chambers 2600 may be disposed in an arrangement of A×B (A and B are natural numbers equal to or greater than 1) at one side of the transfer chamber 2401. Herein, A is the number of process chambers 2600 provided in series in the first direction 12, and B is the number of process chambers 2600 provided in series in the third direction 16. When four or six process chambers 2600 are provided at one side of the transfer chamber 2401, the process chambers 2600 may be disposed in an arrangement of 2×2 or 3×2. The number of process chambers 2600 may be increased or decreased. Contrast to the foregoing, the process chambers 2600 may be provided only at one side of the transfer chamber 2401. Further, contrast to the foregoing, the process chambers 2600 may be provided only at one side and both sides of the transfer chamber 2401 in a single layer.

The buffer unit 2200 is disposed between the transfer frame 1400 and the transfer chamber 2401. The buffer unit 2200 provides a space in which the substrate W stays before the substrate W is transferred between the transfer chamber 2401 and the transfer frame 1400. The buffer unit 2200 is provided with slots (not illustrated) on which the substrate W is placed therein, and the slots (not illustrated) are provided in plurality so as to be spaced apart from each other in the third direction 16. In the buffer unit 2200, a surface facing the transfer frame 1400 and a surface facing the transfer chamber 2401 are opened.

The transfer frame 1400 includes an index transfer device which transfers the substrate W between the carrier 1300 seated on the load port 1200 and the buffer unit 2200. The index transfer device of the transfer frame 1400 includes an index rail 1420 and an index robot 1440. A longitudinal direction of the index rail 1420 is provided to be parallel to the second direction 14. The index robot 1440 is installed on the index rail 1420, and linearly moves in the second direction 14 along the index rail 1420. The index robot 1440 includes a base 1441, a body 1442, and an index arm 1443. The base 1441 is installed to be movable along the index rail 1420. The body 1442 is coupled to the base 1441. The body 1442 is provided to be movable in the third direction 16 on the base 1441. Further, the base 1442 is provided to be rotatable on the base 1441. The index arm 1443 is coupled to the body 1442, and is provided to be movable forward and backward with respect to the body 1442. A plurality of index arms 1443 is provided to be individually driven. The index arms 1443 are arranged to be stacked while being spaced apart from each other in the third direction 16. Some of the index arms 1443 may be used when the substrate W is transferred from the process module 2000 to the carrier 1300, and the other may be used when the substrate W is transferred from the carrier 1300 to the process module 2000. This may prevent particles generated from the substrate W before the process processing from being attached to the substrate W after the process processing in the process of loading and unloading the substrate W by the index robot 1440. Although not illustrated, the index transfer device installed on the transfer frame 1400 may be a driving unit for driving the index robot 1440, and the moving unit of the magnetic levitation type substrate transport device illustrated in FIGS. 2 to 8 may be applied.

The transfer chamber 2401 provides a space for transferring the substrate W between the buffer unit 2200 and the process chamber 2600, and between the process chambers 2600. The magnetic levitation type substrate transfer device 2400 is provided in the transfer chamber 2401. The substrate transfer device 2400 may include a robot unit 2410 and a moving unit 2420 for moving the robot unit 2410 in the magnetic levitation manner. The moving unit has been described with reference to FIGS. 2 to 8, so that the description thereof will be omitted.

A substrate processing apparatus 10 for performing a cleaning process on the substrate W is provided in the process chamber 2600. The substrate processing apparatus 10 provided in each process chamber 2600 may have a different structure according to the type of cleaning process performed. Optionally, the substrate processing apparatus in each process chamber 2600 may have the same structure. Optionally, the process chambers 2600 are divided into a plurality of groups, and the substrate processing apparatuses provided to the process chamber 2600 belonging to the same group may have the same structure, and the substrate processing apparatuses provided to the process chamber 2600 belonging to different groups may have different structures. For example, when the process chambers 2600 are divided into two groups, the process chambers 2600 of a first group may be provided to one side of the transfer chamber 2400, and the process chambers 2600 of a second group may be provided to the other side of the transfer chamber 2400. Optionally, at each of the one side and the other side of the transfer chamber 2400, the process chambers 2600 of the first group may be provided to a lower layer, and the process chambers 2600 of the second group may be provided to an upper layer. The process chambers 2600 of the first group and the process chambers 2600 of the second group may be classified according to the type of chemical used or the type of cleaning method.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. A substrate transfer device comprising:
a robot unit; and
a moving unit configured to move the robot unit in a magnetic levitation manner along a first direction (X axis),
wherein the moving unit includes:
a moving body including an electromagnet module that provides power for magnetic levitation; and
a rail structure with a guide rail installed along the first direction to define a movement path of the moving body, and
the electromagnet module includes:
a body;
electromagnets provided on an upper surface, a lower surface, and one side surface of the body, the electromagnets being configured to levitate and guide the moving body; and
an epoxy molding part formed by molding the body and the electromagnets with an epoxy resin.

2. The substrate transfer device of claim 1, wherein the electromagnet module further includes gap sensors fixed to the body and configured to measure a levitation directional gap and a guide directional gap of the moving body, and
the gap sensors are embedded in the epoxy molding part.

3. The substrate transfer device of claim 2, wherein the electromagnets include an upper electromagnet provided on the upper surface of the body to levitate the moving body in a levitation direction (Z-axis), a lower electromagnet provided on a lower surface of the body, and a guide electromagnet provided on one side surface of the body to guide the moving body in a horizontal direction (Y-axis).

4. The substrate transfer device of claim 3, wherein the body includes:
a first core formed to protrude upwardly from the upper surface of the body and inserted into a coil of the upper electromagnet;
a second core formed to protrude downwardly from the lower surface of the body and inserted into a coil of the lower electromagnet; and
a third core formed to protrude laterally from one side of the body and inserted into a coil of the guide electromagnet.

5. The substrate transfer device of claim 4, wherein the first core, the second core, and the third core are provided such that the ends of the cores protrude from a surface of the epoxy molding part.

6. The substrate transfer device of claim 2, wherein each of the electromagnets includes a core and a coil provided to surround the core, and
the core is integrally formed with the body.

7. The substrate transfer device of claim 3, wherein the rail structure further includes a base plate extending along the first direction, and
the guide rail is provided on an upper portion of the base plate and surrounds the electromagnet module and is open toward the outside of the movement path.

8. The substrate transfer device of claim 7, wherein the guide rail has a ‘C’-shape that is open to the outside.

9. The substrate transfer device of claim 7, wherein the moving body further includes a moving plate supporting the robot unit,
the electromagnet modules are disposed on front opposite sides and rear opposite sides of the moving plate, respectively,
an amplifier consisting of a power amplifier that supplies current is connected to the electromagnet module, and
the amplifier is disposed on opposite sides of the moving plate to be positioned between the electromagnet modules.

10. The substrate transfer device of claim 2, further comprising:
a linear motor configured to provide propulsive force to the moving body.

11. The substrate transfer device of claim 9, wherein the moving body further includes:
a side guide roller provided on the moving plate and configured to rotate while contacting a side surface of the guide rail; and
an upper guide roller provided on the moving plate and configured to rotate while contacting an upper surface of the guide rail.

12. A substrate processing apparatus comprising:
process chambers which are arranged along a first direction (X axis) and in which a process is performed on a substrate;
a robot unit including a hand supporting the substrate to transfer the substrate to the process chamber; and
a moving unit configured to move the robot unit in a magnetic levitation manner along the first direction,
wherein the moving unit includes:
a moving body including an electromagnet module that provides power for magnetic levitation; and
a rail structure with a guide rail installed along the first direction to define a movement path of the moving body, and
the electromagnet module includes:
a body;
electromagnets provided on an upper surface, a lower surface, and one side surface of the body and for levitating and guiding the moving body;
gap sensors fixed to the body and for measuring a levitation directional gap and a guide directional gap of the moving body; and
an epoxy molding part formed by molding the body, the electromagnets, and the gap sensors with an epoxy resin.

13. The substrate processing apparatus of claim 12, wherein the electromagnets include an upper electromagnet disposed on the upper surface of the body to levitate the moving body in a levitation direction (Z-axis), a lower electromagnet provided on the lower surface of the body, and a guide electromagnet provided on one side surface of the body to guide the moving body in a horizontal direction (Y-axis).

14. The substrate processing apparatus of claim 13, wherein the body includes:
a first core formed to protrude upwardly from the upper surface of the body and surrounded by a coil of the upper electromagnet;
a second core formed to protrude downwardly from the lower surface of the body and surrounded by a coil of the lower electromagnet; and
a third core formed to protrude laterally from one side of the body and surrounded by a coil of the guide electromagnet.

15. The substrate processing apparatus of claim 14, wherein the first core, the second core, and the third core are provided such that the ends of the cores protrude from a surface of the epoxy molding part.

16. The substrate processing apparatus of claim 14, wherein the rail structure further includes a base plate extending along the first direction, and
the guide rail is provided on an upper portion of the base plate and has a “C”-shape that surrounds the electromagnet module and is open toward the outside of the movement path.

17. The substrate processing apparatus of claim 14, wherein the moving body further includes a moving plate supporting the robot unit,
the electromagnet modules are disposed on front opposite sides and rear opposite sides of the moving plate, respectively,
an amplifier consisting of a power amplifier that supplies current is connected to the electromagnet module, and
the amplifier is disposed on opposite sides of the moving plate to be positioned between the electromagnet modules.

18. A substrate transfer device comprising:
a robot unit including a hand supporting the substrate to transfer the substrate to a process chamber; and
a moving unit for moving the robot unit in a magnetic levitation manner along the first direction,
wherein the moving unit includes:
a moving body including a moving plate supporting the robot unit and electromagnet modules providing levitation force for magnetic levitation of the moving plate;
a rail structure with a guide rail installed along the first direction on a base plate to provide a movement path of the moving body; and
a linear motor provided between the moving body and the rail structure and providing propulsive force to the moving body,
the electromagnet module includes:
a body mounted on the moving plate by a fixing bracket;
electromagnets provided on an upper surface, a lower surface, and one side surface of the body and for levitating and guiding the moving body;
gap sensors fixed to the body and for measuring a levitation directional gap and a guide directional gap of the moving body; and
an epoxy molding part formed by molding the body, the electromagnets, and the gap sensors with an epoxy resin, and
the guide rail has a ‘C’-shape that surrounds the electromagnet module and is open toward the outside of the movement path.

19. The substrate transfer device of claim 18, wherein the electromagnets include an upper electromagnet provided on the upper surface of the body to levitate the moving body in a levitation direction (Z-axis), a lower electromagnet provided on the lower surface of the body, and a guide electromagnet provided on one side surface of the body to guide the moving body in a horizontal direction (Y-axis), and
the body includes:
a first core formed to protrude upwardly from the upper surface of the body and surrounded by a coil of the upper electromagnet;
a second core formed to protrude downwardly from the lower surface of the body and surrounded by a coil of the lower electromagnet; and
a third core formed to protrude laterally from one side of the body and surrounded by a coil of the guide electromagnet.

20. The substrate transfer device of claim 19, wherein the first core, the second core, and the third core are provided such that ends of the cores protrude from a surface of the epoxy molding part,
the electromagnet modules are disposed on front opposite sides and rear opposite sides of the moving plate, respectively,
an amplifier consisting of a power amplifier that supplies current is connected to the electromagnet module, and
the amplifier is disposed on opposite sides of the moving plate to be positioned between the electromagnet modules.
